(19) United States
(12) Patent Application Publication
(10) Pub. No.: US 2011/0120532 A1
(43) Pub. Date: May 26, 2011

(54) SOLAR MODULE SYSTEM AND METHOD OF MAKING THE SAME

(76) Inventors: Tim Neugent, Des Moines, IA (US); Trent D. Quick, Huxley, IA (US)

(21) Appl. No.: 12/952,810

(22) Filed: Nov. 23, 2010

Related U.S. Application Data
(60) Provisional application No. 61/263,585, filed on Nov. 23, 2009.

(51) Int. Cl. H01L 31/048; H01L 31/042

(52) U.S. Cl. 136/251; 136/244

(57) ABSTRACT

A solar module system having a flexible solar film formed from a layer of photovoltaic film that is adhered to a magnetic member with pressure sensitive adhesive. A junction box is electrically connected to a magnetic member and electrical system of a vehicle such that electricity is transferred from the flexible solar film to the electrical system of the vehicle.

### CROSS REFERENCE TO RELATED APPLICATION

This application claims the benefit of U.S. Provisional Application No. 61/263,585 filed Nov. 23, 2009.

### BACKGROUND OF THE INVENTION

This invention is directed toward a solar module system for providing power to a vehicle and more particularly to providing power to an emergency vehicle.

Presently, conventional vehicles have a number of ancillary devices, separate from the operation of the vehicle, that draw upon power from the vehicles battery such as phones, music systems, GPS systems and the like. This is more so with emergency vehicles that add computer systems and flashing lights. These ancillary devices place stress upon the vehicles power system creating obstacles to maintaining and recharging the power supply. As such, a need exists in the art for a system that is easily attached to a vehicle to provide additional power to the various electrical systems of the vehicle and recharge the vehicle's battery. Thus, a principle object of the present is to provide a solar module system that is easy to install and provides a large surface from which to obtain solar power.

These and other features, advantages, and attributes will be further discussed in the specification and claims.

### BRIEF SUMMARY OF THE INVENTION

A solar module system that has a flexible solar film that is formed from a photovoltaic film. A magnetic member is secured to the flexible solar film and a junction box is electrically connected to the magnetic member to transfer electricity generated from the solar film. The system is then attached to a vehicle such as a police car wherein the junction box is electrically connected to the electrical system of the vehicle in order to transfer electricity from the flexible solar film to the electrical system of the vehicle.

### BRIEF DESCRIPTION OF THE DRAWINGS

FIG. 1 is a schematic diagram of the solar module system;

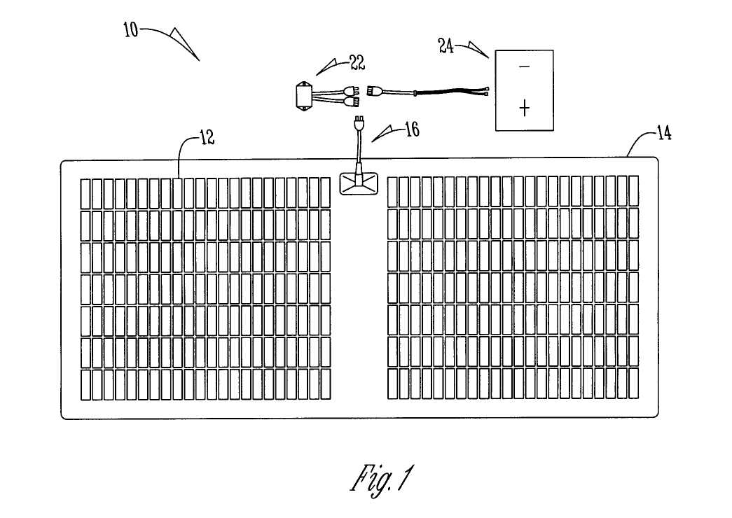

FIG. 2 is a perspective view of the solar module system; and

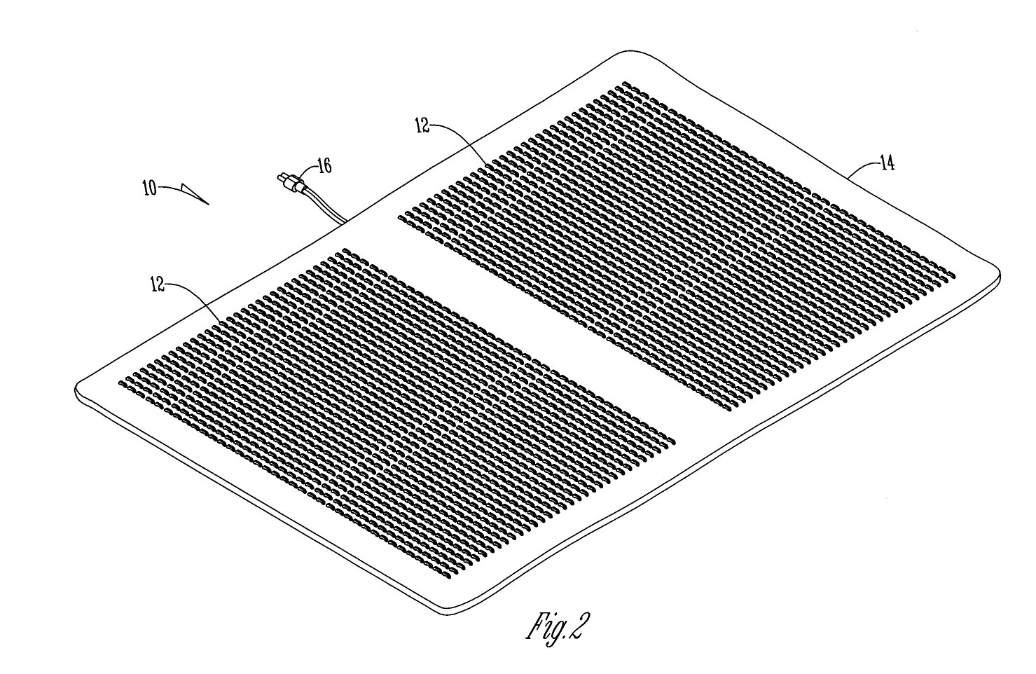

FIG. 3 is a perspective view of a solar module system on a vehicle.

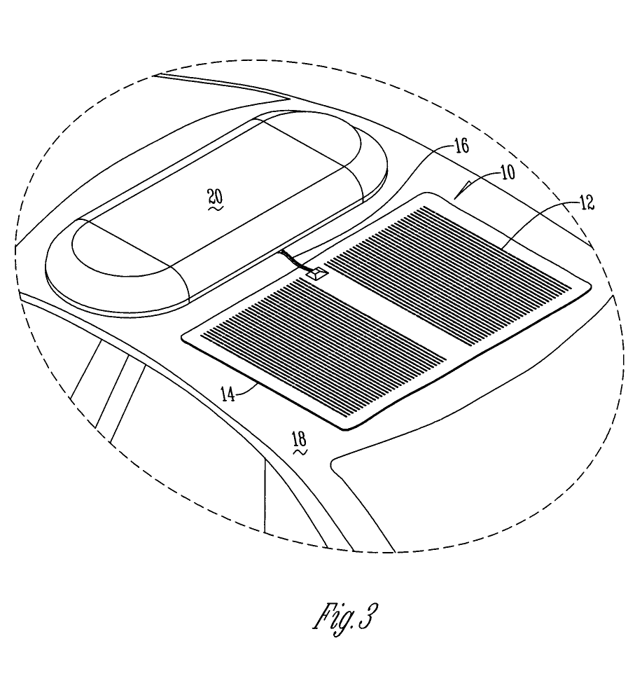

### DETAILED DESCRIPTION OF THE PREFERRED EMBODIMENT

Referring to the Figures, the system 10 has a solar film 12 such as a thin flexible layer of photovoltaic film having monolithic integration. The solar film 12 is laminated, preferably through a vacuum lamination process, with a UV stable protective to encapsulate the film 12. In one exemplary example a protective encapsulate is placed on the top of the film and a thermal adhesive on the bottom of the film such that the film is sandwiched between the two.

Once laminated, the film 12 is attached to a magnetic sheet 14, preferably having a non-magnetic side and a magnetic side. More specifically, the back of the laminated film 12 is first attached to the non-magnetic side of the magnetic strip 14, using a pressure sensitive adhesive. Then adhesive is applied to the top of the laminated film 12, extended over the edge of the system and attached to the magnetic side of the magnetic strip. Finally, a junction box 16 is attached to the magnetic sheet 14 or other part of the system 10 through any conventional means such as rivets.

Once assembled, the module 10 is attached to a vehicle 18 and connected to the electrical system such as a light bar 20 or other device such as a solar controller 22 and battery 24. To attach the system 10 to the vehicle 18, the application surface of the vehicle is cleaned, preferably with an alcohol based cleaning solution. If desired, a section is cut from the module 10 and formed to receive the antenna of the vehicle 18 which aids in theft prevention. Then the module 10 is placed on the application surface such that the module 10 is magnetically attached. Once attached, the junction box 16 is electrically connected to a device on the vehicle 18 such as a light bar 20 of a police car, or the main power supply.

The size and shape of the module is adapted to different vehicles, and is connected to devices other than the light bar 20 to prevent leakage and damage of the light bar 20. The primary advantages of the module is that it is easy to install and provides a large surface from which to obtain solar power.

It will be appreciated by those skilled in the art that other various modifications could be made to the device without departing from the spirit and scope of this invention. All such modifications and changes fall within the scope of the claims and are intended to be covered thereby.

What is claimed is:

1. A solar module system comprising:
a flexible solar film formed from a layer of photovoltaic film;
a magnetic member secured to the flexible solar film; and
a junction box electrically connected to the magnetic member to transfer electricity generated from the flexible solar film.

2. The system of claim 1 wherein the flexible solar film is encapsulated with a UV stable protective laminate.

3. The system of claim 1 wherein the magnetic member is adhered to the flexible solar film with a pressure sensitive adhesive.

4. The system of claim 1 wherein the junction box is electrically connected to an electrical system of a vehicle to transfer electricity to the vehicle.

5. The system of claim 4 wherein the junction box is electrically connected to the electrical system of the vehicle through a light bar of the vehicle.
